(19) United States
(12) Patent Application Publication
(10) Pub. No.: US 2006/0150068 A1
(43) Pub. Date: Jul. 6, 2006

(54) Parity signal generator

(75) Inventors: Moon-Seok Yang, Chungcheongbuk-do (KR); Myung-Woo Lee, Chungcheongbuk-do (KR)

Correspondence Address: MORGAN LEWIS & BOCKIUS LLP, 1111 PENNSYLVANIA AVENUE NW, WASHINGTON, DC, 20004, US

(73) Assignee: MagnaChip Semiconductor, Ltd.

(21) Appl. No.: 11/320,831

(22) Filed: Dec. 30, 2005

(30) Foreign Application Priority Data
Dec. 30, 2004 (KR) 2004-0116011

(51) Int. Cl. G06F 11/00; H03M 13/00

(52) U.S. Cl. 714/801

(57) ABSTRACT

Provided is a parity signal generator for generating a parity signal by continuously detecting a horizontal sync signal. The parity signal generator includes a first detecting unit for generating a first detection signal by detecting whether the number of a horizontal sync signal is odd or even during an activation of a vertical sync signal; a second detecting unit for generating a second detection signal by detecting whether the number of the horizontal sync signal is odd or even during an inactivation of the vertical sync signal; and an output unit for receiving the first and second detection signals to output a parity signal.

### FIELD OF THE INVENTION

The present invention relates to a display driver IC device; and, more particularly, to a parity signal generator for continuously generating a parity signal.

### DESCRIPTION OF THE RELATED ART

When the number of lines of an LCD panel is even, a display driver IC device skips a line inversion one times after one frame is finished, and performs the line inversion after a next frame is finished. On the contrary, when the number of the lines of the LCD panel is odd, the display driver IC device continuously performs a line inversion.

At this point, a parity signal generator generates a parity signal that notifies whether the number of the lines of the LCD panel is even or odd. That is, whether the number of the lines of the LCD panel is even or odd can be known by logic levels of the parity signal.

FIG. 1 is a block diagram showing a conventional parity signal generator.

As shown, the conventional parity signal generator includes a divider 10, an inverter I1, and a latch unit 20. The divider 10 is reset by an initial vertical sync signal VV2 to divide a horizontal sync signal HSYNC_INT by two. The inverter I1 inverts the initial vertical sync signal VV2. The latch unit 20 latches an output signal of the divider 10 in response to an edge of an inverted initial vertical sync signal and outputs it as a parity signal PARITY.

The divider 10 includes an inverter I2 and a latch 12. The inverter I2 inverts an output signal (Q) of the divider 10. The latch 12 receives the initial vertical sync signal VV2 as a reset signal (RESET), the horizontal sync signal HSYNC_INT as a clock (CLK), and an output signal of the inverter I2 as a data (D).

The initial vertical sync signal VV2 is a vertical sync signal when the display driver IC device is initially driven. The initial vertical sync signal VV2 is not activated because the vertical sync signal is not outputted as the initial vertical sync signal, except the initial driving.

An operation of the display driver IC device will be described below in brief.

The divider 10 resets the output signal (Q) in response to the initial vertical signal vv2 activated during one frame, and divides the horizontal sync signal HSYNC_INT by two. Then, the latch unit 20 outputs the output signal of the divider 10 as the parity signal in response to a falling edge of the initial vertical sync signal VV2.

That is, the divider 10 divides the horizontal sync signal HSYNC_INT, which is applied during the activation of the initial vertical sync signal VV2, by two. Therefore, at a time point when the initial vertical sync signal VV2 is inactivated, the output signal of the divider 10 has a logic low level when the number of the horizontal sync signal HSYNC_INT is odd, and a logic high level when the number of the horizontal sync signal HSYNC_INT is even.

Accordingly, the latch unit 20 activated in response to the inactivation of the initial vertical sync signal VV2 outputs the parity signal of a logic low level when the number of the horizontal sync signal HSYNC_INT applied during one period of the initial vertical sync signal VV2 is odd, and the parity of a logic high level when the number of the horizontal sync signal HSYNC_INT is even.

Meanwhile, when the parity signal has the logic low level, the number of the lines is odd. Therefore, the display driver IC device with the parity signal generator continuously inverts the lines of the display device to other polarity.

Also, when the parity signal has the logic high level, the number of the lines is even. Therefore, after one frame is finished, the display driver IC device inverts the lines of the display device into other polarity.

However, as illustrated in FIG. 2, in the parity signal generator as shown in FIG. 1, the initial vertical sync signal VV2 is activated only when the display driver IC device is initially driven, and it is not activated thereafter. As a result, the parity signal generator of FIG. 1 may generate an incorrect parity signal because it cannot determine the odd or the even number of the horizontal sync signal HSYNC_INT when the display driver IC device is not initially driven.

### SUMMARY OF THE INVENTION

It is, therefore, an object of the present invention to provide a parity signal generator for generating a parity signal by continuously detecting a horizontal sync signal.

In accordance with an aspect of the present invention, there is provided a parity signal generator including: a first detecting unit for generating a first detection signal by detecting whether the number of a horizontal sync signal is odd or even during an activation of a vertical sync signal; a second detecting unit for generating a second detection signal by detecting whether the number of the horizontal sync signal is odd or even during an inactivation of the vertical sync signal; and an output unit for receiving the first and second detection signals to output a parity signal.

In accordance with another aspect of the present invention, there is provided a display device including: a panel for displaying an image data in response to a horizontal sync signal and a vertical sync signal; and a driver including a parity signal generator, for transferring the image data with the horizontal sync signal and the vertical sync signal based on a parity signal, wherein the parity signal generator generates the parity signal by detecting whether the horizontal sync signal is even or odd according to a status of the vertical sync signal.

### BRIEF DESCRIPTION OF THE DRAWINGS

The above and other objects and features of the present invention will become apparent from the following description of the preferred embodiments given in conjunction with the accompanying drawings, in which:

FIG. 1 is a block diagram showing a conventional parity signal generator;

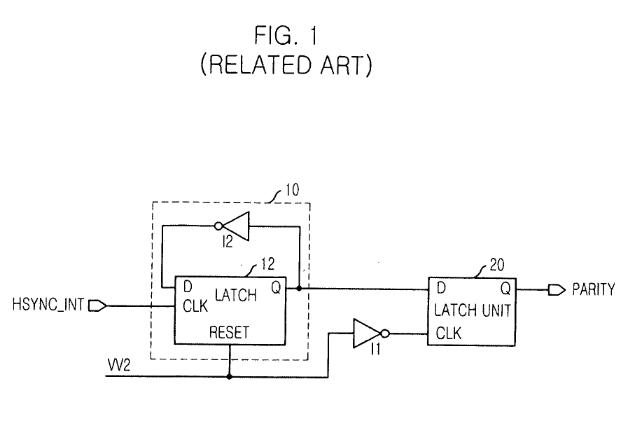

FIG. 2 is a simulation waveform illustrating signals used in the conventional parity signal generator of FIG. 1;

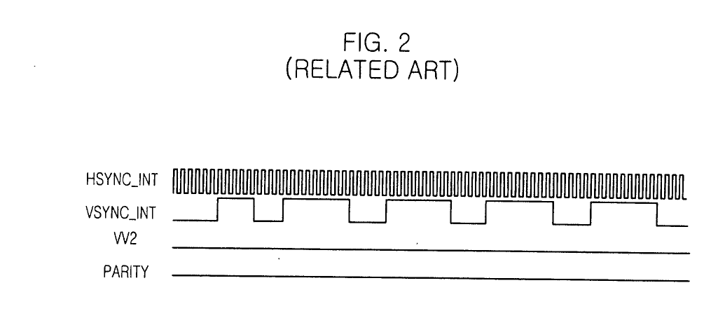

FIG. 3 is a circuit diagram depicting a parity signal generator in accordance with an embodiment of the present invention; and

FIG. 4 is a simulation waveform illustrating signals used in the parity signal generator of FIG. 3.

### DETAILED DESCRIPTION OF THE INVENTION

A parity signal generator in accordance with exemplary embodiments of the present invention will be described in detail with reference to the accompanying drawings.

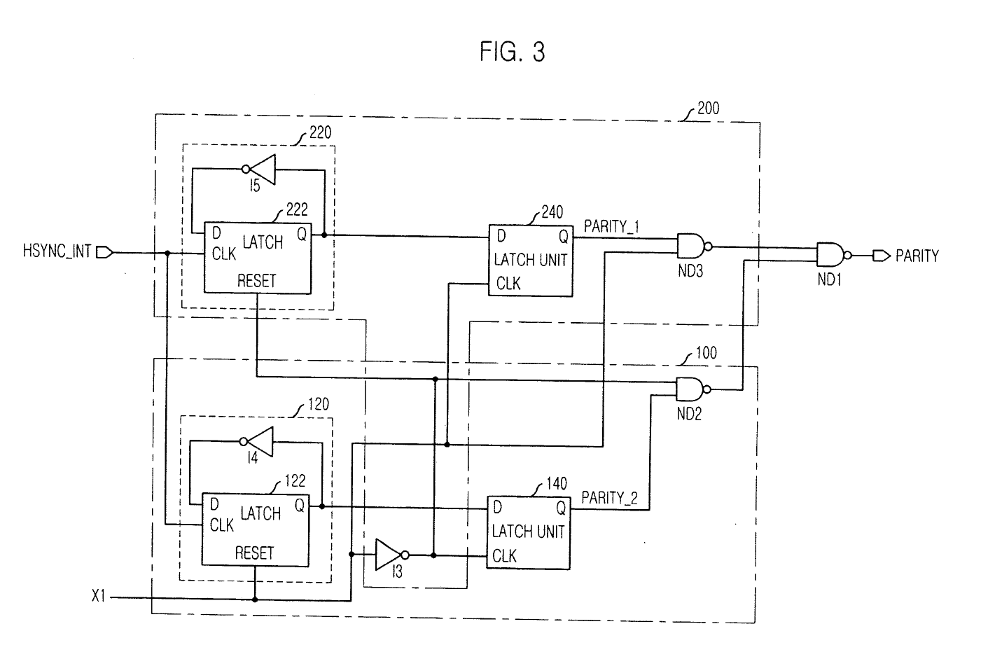

FIG. 3 is a circuit diagram depicting a parity signal generator in accordance with an embodiment of the present invention.

As shown, the parity signal generator includes a first detecting unit 100, a second detecting unit 200, and an output unit ND1. The first detecting unit 100 generates a first detection signal by detecting whether the number of horizontal sync signal HSYNC_INT applied during the activation of a vertical sync signal X1 is odd or even. The second detecting unit 200 generates a second detection signal by detecting whether the number of the horizontal sync signal HSYNC_INT applied during the inactivation of the vertical sync signal X1 is odd or even. The output unit ND1 receives the first and second detection signals to output a parity signal PARITY.

The first detecting unit 100 includes a divider 120, an inverter I3, a latch 140, and a NAND gate ND2. The divider 120 is reset by the vertical sync signal X1 to divide the horizontal sync signal HSYNC_INT by two. The inverter I3 inverts the vertical sync signal X1. The latch 140 latches an output signal of the divider 120 in response to an edge of an inverted vertical sync signal. Also, the NAND gate ND2 receives an output signal PARITY_2 of the latch 140 and an output signal of the inverter I3 to output the first detection signal.

The divider 120 includes an inverter I4 and a latch 122. The inverter I4 inverts an output signal (Q) of the divider 120. The latch 122 receives the vertical sync signal X2 as a reset signal (RESET), the horizontal sync signal HSYNC_INT as a clock (CLK), and an output signal of the inverter I4 as a data (D).

The second detecting unit 200 includes the inverter I3, a divider 220, a latch 240, and a NAND gate ND3. The inverter I3 inverts the vertical sync signal X1. The divider 220 is reset by an output signal of the inverter I3 to divide the horizontal sync signal HSYNC_INT by two. The latch 240 latches an output signal of the divider 220 in response to an edge of the vertical sync signal X1. The NAND gate ND3 receives an output signal PARITY_1 of the latch 240 and the vertical sync signal X1 to output the second detection signal.

The divider 220 includes an inverter I5 and a latch 222. The inverter I5 inverts an output signal (Q) of the divider 220. The latch 222 receives the output signal of the inverter I3 as a reset signal (RESET), the horizontal sync signal HSYNC_INT as a clock (CLK), and an output signal of the inverter I5 as a data (D).

The output unit ND1 is configured with a NAND gate receiving the first and second detection signals to output the parity signal PARITY.

An operation of the parity signal generator illustrated in FIG. 3 will be described below.

During the activation of the vertical sync signal X1, the divider 120 of the second detecting unit 100 divides the horizontal sync signal HSYNC_INT by two, and the latch 140 latches the output signal of the divider 120 at an inactivated edge of the vertical sync signal X1. Then, the NAND gate ND2 maintains the first detection signal to a logic high level while the vertical sync signal X1 is in an activated state, and inverts the output signal PARITY_2 of the latch 140 to thereby output the inverted signal as the first detection signal when the vertical sync signal X1 is inactivated.

During the inactivation of the vertical sync signal X1, the divider 220 of the second detecting unit 200 divides the horizontal sync signal HSYNC_INT by two, and the latch 240 latches the output signal of the divider 220 at an activated edge of the vertical sync signal X1. Then, the NAND gate ND3 maintains the second detection signal to a logic high level while the vertical sync signal X1 is in an inactivated state, and inverts the output signal PARITY_1 of the latch 240 to thereby output the inverted signal as the second detection signal when the vertical sync signal X1 is activated.

Accordingly, since the first detection signal maintains the logic high level while the vertical sync signal X1 is in the activated state, the output unit ND1 inverts the second detection signal to output the parity signal PARITY. Also, since the second detection signal maintains the logic high level while the vertical sync signal X1 is in the inactivated state, the output unit ND1 inverts the first detection signal to output the parity signal PARITY.

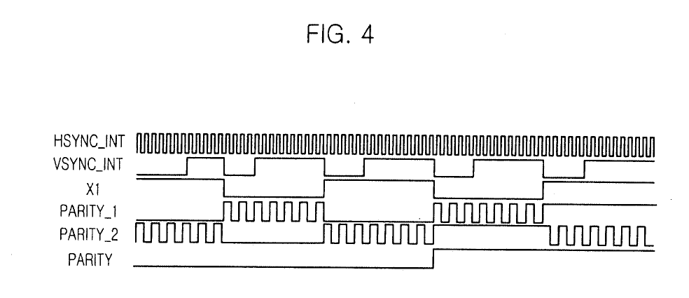

FIG. 4 is a simulation waveform illustrating the parity signal generator illustrated in FIG. 3.

As shown, while the vertical sync signal X1 is in the activated state, the parity signal generator generates the parity signal PARITY by determining whether the number of the horizontal sync signal HSYNC_INT is odd or even through the first detecting unit 100. On the contrary, while the vertical sync signal X1 is in the inactivated state, the parity signal generator generates the parity signal PARITY by determining whether the number of the horizontal sync signal HSYNC_INT is odd or even through the second detecting unit 200.

That is, the parity signal generator in accordance with the present invention generates the parity signal by continuously determining whether the number of the horizontal sync signal is odd or even. Therefore, when the variation occurs, the parity signal to which the variation is reflected is generated.

The present application contains subject matter related to the Korean patent application No. 2004-116011, filed in the Korean Patent Office on Dec. 30, 2004, the entire contents of which being incorporated herein by reference.

While the present invention has been described with respect to the particular embodiments, it will be apparent to those skilled in the art that various changes and modifications may be made without departing from the scope of the invention as defined in the following claims.

What is claimed is:

1. A parity signal generator, comprising:
a first detecting unit for generating a first detection signal by detecting whether the number of a horizontal sync signal is odd or even during an activation of a vertical sync signal;
a second detecting unit for generating a second detection signal by detecting whether the number of the horizontal sync signal is odd or even during an inactivation of the vertical sync signal; and
an output unit for receiving the first and second detection signals to output a parity signal.

2. The parity signal generator as recited in claim 1, wherein the first detecting unit includes:
a first divider configured to be reset by the vertical sync signal to divide the horizontal sync signal by two;
a first inverter for inverting the vertical sync signal;
a first latch for latching an output signal of the first divider in response to an edge of an output signal of the first inverter; and
a first NAND gate for receiving an output signal of the first latch and the output signal of the first inverter to thereby output the first detection signal.

3. The parity signal generator as recited in claim 2, wherein the first divider includes:
a second inverter for inverting an output signal of the first divider; and
a latch circuit for receiving the vertical sync signal as a reset signal, the horizontal sync signal as a clock, and an output signal of the second as a data.

4. The parity signal generator as recited in claim 2, wherein the second detecting unit includes:
a second divider configured to be reset by the output signal of the first inverter to divide the horizontal sync signal by two;
a second latch for latching an output signal of the second divider in response to an edge of the vertical sync signal; and
a second NAND gate for receiving an output signal of the second latch and the vertical sync signal to thereby output the second detection signal.

5. The parity signal generator as recited in claim 4, wherein the second divider includes:
a second inverter configured to invert an output signal of the second divider; and
a latch circuit configured to receive the output signal of the first inverter as a reset signal, the horizontal sync signal as a clock, and an output signal of the second inverter as a data.

6. The parity signal generator as recited in claim 5, wherein the output unit is configured with a NAND gate receiving the first and second detection signals to output the parity signal.

7. A display device, comprising:
a panel for displaying an image data in response to a horizontal sync signal and a vertical sync signal; and
a driver including a parity signal generator, for transferring the image data with the horizontal sync signal and the vertical sync signal based on a parity signal, wherein the parity signal generator generates the parity signal by detecting whether the horizontal sync signal is even or odd according to a status of the vertical sync signal.

8. The display device as recited in claim 7, wherein the parity signal generator includes:
a first detecting unit for generating a first detection signal by detecting whether the number of the horizontal sync signal is odd or even during an activation of the vertical sync signal;
a second detecting unit for generating a second detection signal by detecting whether the number of the horizontal sync signal is odd or even during an inactivation of the vertical sync signal; and
an output unit for receiving the first and second detection signals to output the parity signal.

9. The display device as recited in claim 8, wherein the first detecting unit includes:
a first divider configured to be reset by the vertical sync signal to divide the horizontal sync signal by two;
a first inverter for inverting the vertical sync signal;
a first latch for latching an output signal of the first divider in response to an edge of an output signal of the first inverter; and
a first NAND gate for receiving an output signal of the first latch and the output signal of the first inverter to thereby output the first detection signal.

10. The display device as recited in claim 9, wherein the first divider includes:
a second inverter for inverting an output signal of the first divider; and
a latch circuit for receiving the vertical sync signal as a reset signal, the horizontal sync signal as a clock, and an output signal of the second as a data.

11. The display device as recited in claim 9, wherein the second detecting unit includes:
a second divider configured to be reset by the output signal of the first inverter to divide the horizontal sync signal by two;
a second latch for latching an output signal of the second divider in response to an edge of the vertical sync signal; and
a second NAND gate for receiving an output signal of the second latch and the vertical sync signal to thereby output the second detection signal.

12. The display device as recited in claim 11, wherein the second divider includes:
a second inverter configured to invert an output signal of the second divider; and
a latch circuit configured to receive the output signal of the first inverter as a reset signal, the horizontal sync signal as a clock, and an output signal of the second inverter as a data.

13. The display device as recited in claim 11, wherein the output unit is configured with a NAND gate receiving the first and second detection signals to output the parity signal.
